(19) United States
(12) Patent Application Publication
(10) Pub. No.: US 2024/0298712 A1
(43) Pub. Date: Sep. 12, 2024

(54) AEROSOL GENERATING DEVICE AND METHOD

(71) Applicants: Ju Eon PARK, Gyeonggi-do (KR); Tae Hun KIM, Gyeonggi-do (KR); Sung Wook YOON, Gyeonggi-do (KR); Hyung Jin JUNG, Seoul (KR); Jung Ho HAN, Daejeon (KR)

(72) Inventors: Ju Eon PARK, Gyeonggi-do (KR); Tae Hun KIM, Gyeonggi-do (KR); Sung Wook YOON, Gyeonggi-do (KR); Hyung Jin JUNG, Seoul (KR); Jung Ho HAN, Daejeon (KR)

(73) Assignee: KT&G Corporation, Daejeon (KR)

(21) Appl. No.: 18/563,698

(22) PCT Filed: Jun. 20, 2023
(86) PCT No.: PCT/KR2023/008540

§ 371 Date: Nov. 22, 2023

(30) Foreign Application Priority Data
Jun. 22, 2022 (KR) 10-2022-0076376
Oct. 14, 2022 (KR) 10-2022-0132738

(51) Int. Cl. A24F 40/53; A24F 40/40

(52) U.S. Cl. CPC A24F 40/53; A24F 40/40

(57) ABSTRACT

An aerosol generating device includes: a main body including a semi-exterior portion on a surface of which a 1-1st contact electrode and a 1-2nd contact electrode are formed to be apart from each other; a cover detachably coupled to the main body and including a 2-1st contact electrode corresponding to the 1-1st contact electrode and a 2-2nd contact electrode corresponding to the 1-2nd contact electrode; and a controller configured to determine that the cover is mounted on the main body when the 1-1st contact electrode and the 1-2nd contact electrode are electrically connected to each other.

### TECHNICAL FIELD

The disclosure relates to an aerosol generating device and method. Particularly, the disclosure relates to an aerosol generating device and method capable of physically determining whether or not a cover is detached.

### BACKGROUND ART

Recently, the demand for smoking methods to replace traditional cigarettes has increased. For example, there is growing demand for an aerosol generating method for generating aerosols by heating an aerosol generating material in cigarettes, rather than by combusting cigarettes. Accordingly, research into a heating-type cigarette or a heating-type aerosol generating device has been actively conducted.

An aerosol generating device may include a main body portion and a cover. The main body portion may include a heater for heating a cigarette, and when the heater operates in a state in which the cover is removed, a user may have the risk of burns.

However, when whether or not the cover is detached is determined by using an inductive sensor, a recognition error may occur due to heating noise.

### DISCLOSURE OF INVENTION

### Technical Problem

The disclosure provides an aerosol generating device for determining whether or not a cover is detached by using a physical method and an operating method of the aerosol generating device.

The disclosure provides an aerosol generating device for improving connection accuracy of an electrode arranged in a semi-exterior portion and an electrode arranged in a cover and an operating method of the aerosol generating device.

The problems to be solved by one or more embodiments are not limited to those described above, and other objectives that are not described may be clearly understood by one of ordinary skill in the art from the present specification and the accompanying drawings.

### Solution to Problem

An aerosol generating device according to an embodiment includes a main body including a semi-exterior portion on a surface of which a 1-1st contact electrode and a 1-2nd contact electrode are formed to be apart from each other, a cover detachably coupled to the main body and including a 2-1st contact electrode corresponding to the 1-1st contact electrode and a 2-2nd contact electrode corresponding to the 1-2nd contact electrode, and a controller configured to determine that the cover is mounted on the main body when the 1-1st contact electrode and the 1-2nd contact electrode are electrically connected to each other.

An operating method of an aerosol generating device including a main body that includes a semi-exterior portion on a surface of which a 1-1st contact electrode and a 1-2nd contact electrode are formed to be apart from each other, and a cover detachably coupled to the main body and including a 2-1st contact electrode corresponding to the 1-1st contact electrode and a 2-2nd contact electrode corresponding to the 1-2nd contact electrode, according to an embodiment, includes transmitting an output signal of a high level to a general-purpose input and output terminal, receiving an input signal through the general-purpose input and output terminal, and determining, based on a change of the input signal, whether or not the cover and the main body are coupled to each other.

### Advantageous Effects of Invention

According to an aerosol generating device and method, according to various embodiments of the disclosure, whether or not a cover is detached may be determined by using a physical method, according to which an electrode arranged in a semi-exterior portion and an electrode arranged in a cover are connected to each other, and a signal level change of one electrode is detected.

Also, according to the aerosol generating device and method, according to various embodiments of the disclosure, connection accuracy of the electrode arranged in the semi-exterior portion and the electrode arranged in the cover may be improved by adding magnetic substances in the electrodes.

The effects according to one or more embodiments are not limited to those described above, and other advantages that are not described may be clearly understood by one of ordinary skill in the art from this specification and the accompanying drawings.

### BRIEF DESCRIPTION OF DRAWINGS

FIG. 1 is a perspective view of an aerosol generating device into which an aerosol generating article is inserted, according to an embodiment.

FIG. 2 is an exploded side view schematically illustrating the exterior of an aerosol generating device according to an embodiment.

FIG. 3 is an exploded perspective view showing a state in which a cover of the aerosol generating device illustrated in FIG. 2 is separated from a main body.

FIG. 4A is a plan view of a top plate of a semi-exterior portion, and FIG. 4B is a bottom view of the top plate of the semi-exterior portion.

FIG. 5A is a bottom view of a cover, and FIG. 5B is a plan view of the cover from which a top plate is removed.

FIG. 6 is a cross-sectional view of an aerosol generating device according to an embodiment, for describing a coupling state between contact electrodes when a cover is coupled to a main body.

FIG. 7 is a cross-sectional view of an aerosol generating device according to another embodiment, for describing a coupling state between contact electrodes when a cover is coupled to a main body.

FIG. 8 is a block diagram of an aerosol generating device according to another embodiment.

FIG. 9 is a flowchart for describing a method, performed by an aerosol generating device, of determining whether or not a cover and a main body are detached from each other.

### MODE FOR THE INVENTION

Regarding the terms in the various embodiments, the general terms which are currently and widely used are selected in consideration of functions of structural elements in the various embodiments of the present disclosure. However, meanings of the terms can be changed according to intention, a judicial precedence, the appearance of a new technology, and the like. In addition, in certain cases, terms which can be arbitrarily selected by the applicant in particular cases. In such a case, the meaning of the terms will be described in detail at the corresponding portion in the description of the present disclosure. Therefore, the terms used in the various embodiments of the present disclosure should be defined based on the meanings of the terms and the descriptions provided herein.

In addition, unless explicitly described to the contrary, the word “comprise” and variations such as “comprises” or “comprising” will be understood to imply the inclusion of stated elements but not the exclusion of any other elements. In addition, the terms “-er”, “-or”, and “module” described in the specification mean units for processing at least one function and operation and can be implemented by hardware components or software components and combinations thereof.

Hereinafter, an embodiment of the disclosure will be described in detail with reference to the accompanying drawings so that one of ordinary skill in the art may easily execute the embodiment of the disclosure. However, the disclosure may be embodied in many different forms and should not be construed as being limited to the embodiments set forth herein.

Hereinafter, embodiments of the disclosure will be described in detail with reference to the drawings.

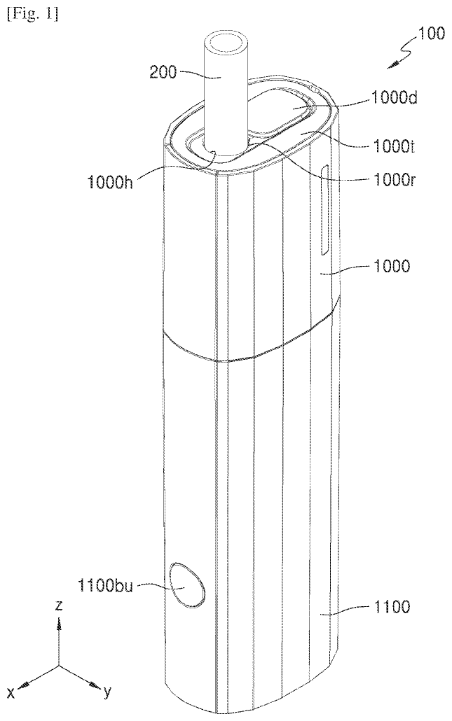

FIG. 1 is a perspective view of an aerosol generating device into which an aerosol generating article is inserted, according to an embodiment.

Referring to FIG. 1, an aerosol generating device 100 according to an embodiment may include a cover 1000 and a main body 1100.

The cover 1000 may be coupled to one end of the main body 1100, so that the main body 1100 and the cover 1000 may together form the exterior of the aerosol generating device 100. An external hole 1000h through which an aerosol generating article 200 may be inserted may be formed in an upper surface of the cover 1000 coupled to the main body 1100.

The main body 1100 may form a portion of the exterior shape of the aerosol generating device 100 and may accommodate and protect components of the aerosol generating device 100. For example, a battery (not shown), a processor (not shown), and/or a heater (not shown) may be accommodated in the main body 1100. However, the disclosure is not limited thereto. Also, the main body 1100 may accommodate the aerosol generating article 200 inserted through the external hole 1000h.

The main body 1100 and the cover 1000 may be formed of a plastic material with low conductivity, or a metal material, a surface of which is coated with a heat-blocking material. The main body 1100 and the cover 1000 may be, for example, formed by injection molding, three-dimensional (3D) printing, or assembling of small components formed by injection molding.

A maintaining device (not shown) for maintaining a coupling state of the main body 1100 and the cover 1000 may be formed between the main body 1100 and the cover 1000. The maintaining device may include, for example, a protrusion and a groove. The coupling state of the cover 1000 and the main body 1100 may be maintained by maintaining a state in which the protrusion is inserted into the groove, and the protrusion may be separated from the groove as the protrusion moves according to a manipulation button through which a user input is applied.

The external hole 1000h through which the aerosol generating article 200 may be inserted may be formed in the upper surface of the cover 1000 coupled to the main body 1100. Also, a rail 1000r may be formed on a position of the upper surface of the cover 1000 to be adjacent to the external hole 1000h. A door 1000d capable of a sliding movement along the upper surface of the cover 1000 may be formed at the rail 1000r. The door 1000d may linearly and slidingly move along the rail 1000r. A top plate 1000t in which an opening is formed along a movement path of the door 1000d may be arranged on the upper surface of the cover 1000.

The door 1000d may move along the rail 1000r so as to externally expose the external hole 1000h, through which the aerosol generating article 200 may be inserted into the main body 1100 by passing through the cover 1000.

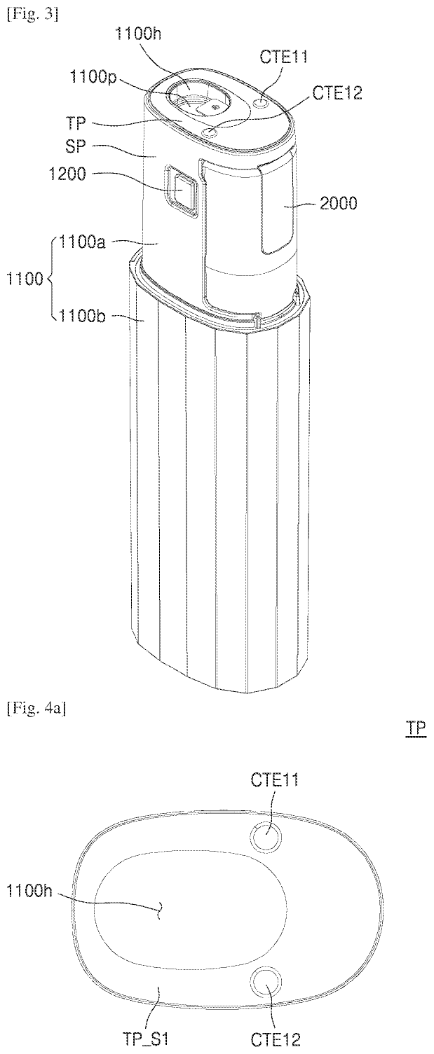

When the external hole 1000h is exposed to the outside by the door 1000d, a user may insert the aerosol generating article 200 into the external hole 1000h and an insertion hole 1100h (of FIG. 3) to mount the aerosol generating article 200 in an accommodation passage 1100p (of FIG. 3) formed in the cover 1000.

The rail 1000r may have a concave groove shape. However, according to an embodiment, the rail 1000r is not limited to a particular shape. For example, the rail 1000r may have a convex shape and may extend in a curved shape rather than a linear shape.

A manipulation button 1100bu may be formed in the main body 1100. As the manipulation button 1100bu is manipulated, operations of the aerosol generating device 100 may be controlled.

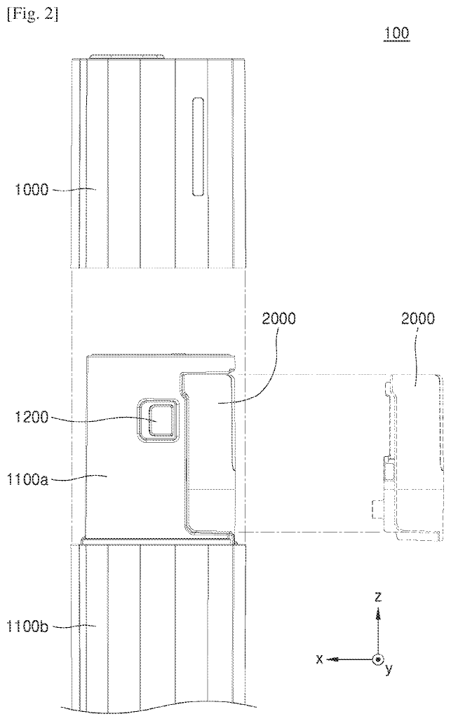

FIG. 2 is an exploded side view schematically illustrating the exterior of an aerosol generating device according to an embodiment.

Referring to FIG. 2, the aerosol generating device 100 according to an embodiment may include the cover 1000, the main body 1100, a button 1200, and a cartridge 2000.

The main body 1100 may include a semi-exterior portion 1100a into which the aerosol generating article 200 is inserted and to which the cartridge 2000 is coupled and a bottom case 1100b supporting and protecting various components mounted in the main body 1100. Hereinafter, the “main body” 1100 denotes both of the semi-exterior portion 1100a and the bottom case 1100b.

The cover 1000 may be released from the coupling with the main body 1100 and may be separated from the main body 1100. For example, the cover 1000 may be separated from the main body 1100 in a +z direction. When the cover 1000 is separated from the main body 1100, the semi-exterior portion 1100a of the main body 1100, the button 1200, and the cartridge 2000 may be exposed to the outside.

The button 1200 may be arranged such that at least a portion of the button 1200 is exposed to the outside of the semi-exterior portion 1100a, and according to a user's input, the button 1200 may release the clamping relationship between the main body 1100 and the cartridge 2000. For example, when the user's input is applied to the button 1200, the cartridge 2000 may be detached from the semi-exterior portion 1100a.

The cartridge 2000 may store an aerosol generating material and may be detachably coupled to one end of the semi-exterior portion 1100a.

The aerosol generating material may have any one of various states, such as a liquid state, a solid state, a gas state, a gel state, etc. The aerosol generating material may include a liquid composition. For example, the liquid composition may be a liquid including a tobacco-containing material having a volatile tobacco flavor component, or a liquid including a non-tobacco material.

The cartridge 2000 may operate according to an electrical signal, a radio signal, or the like transmitted from the main body 1100 to convert a phase of the aerosol generating material in the cartridge 2000 to a gas phase to generate aerosol. The aerosol may denote a gas in a state in which vaporized particles generated from the aerosol generating material and air are mixed.

According to an embodiment, the cartridge 2000 may be coupled to the main body 1100 including a processor (not shown) and/or a battery (not shown) and may be implemented as a component of the aerosol generating device. For example, a heating element (not shown) included in the cartridge 2000 may be electrically connected to the main body 1100, so that the heating element may receive power from the battery, and power supply to the heating element may be controlled by the processor.

That is, in the aerosol generating device 100 including the cartridge 2000, power may be supplied to the heating element, and the supply of power to the heating element may be controlled, and thus, aerosol may be generated from the aerosol generating material in a liquid state or a gel state that is stored in the cartridge 2000.

As another example, the cartridge 2000 may be coupled to the main body 1100 further including an accommodation space (not shown) into which the aerosol generating article is accommodated and a heater (not shown) heating the aerosol generating article accommodated in the accommodation space.

That is, the aerosol generating device including the cartridge 2000 may not only generate aerosol by heating the aerosol generating material stored in the cartridge 2000, but may also generate aerosol by heating the aerosol generating article 200 (of FIG. 1) inserted. Accordingly, a hybrid type of aerosol generating device may be realized.

FIG. 2 illustrates that the cartridge 2000 is coupled to the main body 1100 by approaching the main body 1100 from a side surface of the semi-exterior portion 1100a. However, a coupling method of the cartridge 2000 and the main body 1100 is not limited thereto. For example, like the cover 1000, the cartridge 2000 may be coupled to the main body 1100 by approaching the main body 1100 in a −z direction from a position apart from the main body 1100 in a +z direction.

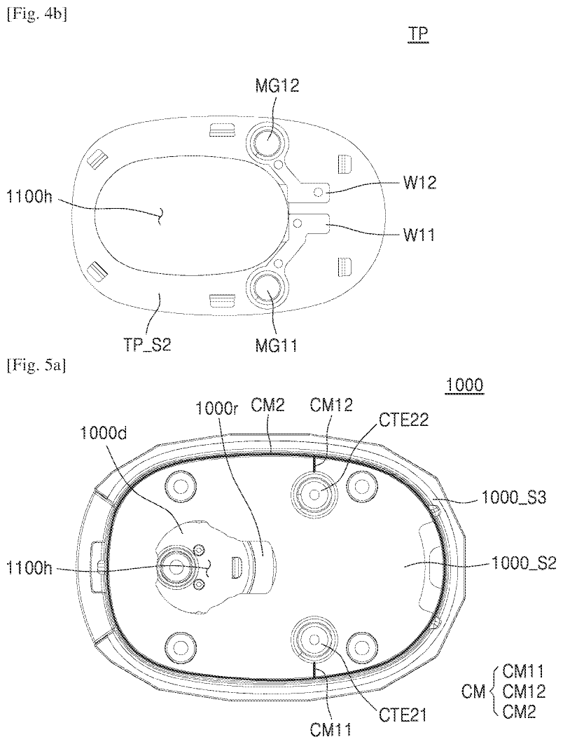

FIG. 3 is an exploded perspective view of a state, in which the cover 1000 of the aerosol generating device 100 illustrated in FIG. 2 is separated from the main body 1100. FIG. 4A is a plan view of a top plate of a semi-exterior portion. FIG. 4B is a bottom view of the top plate of the semi-exterior portion.

Referring to FIG. 3, the aerosol generating device 100 according to an embodiment may include the main body 1100 and the cartridge 2000. At least one of the components of the aerosol generating device 100 according to an embodiment may be the same or substantially the same as at least one of the components of the aerosol generating device 100 illustrated in FIG. 2, and hereinafter, the same descriptions are not repeated.

The semi-exterior portion 1100a may include a 1-1st contact electrode CTE11 and a 1-2nd contact electrode CTE12 on a surface thereof. The 1-1st contact electrode CTE11 and the 1-2nd contact electrode CTE12 may be formed to face a 2-1st contact electrode and a 2-2nd contact electrode formed on an inner surface of the cover 1000 to be described below.

FIG. 3 illustrates that the 1-1st contact electrode CTE11 and the 1-2nd contact electrode CTE12 are formed on a top plate TP of the semi-exterior portion 1100a. However, positions of the 1-1st contact electrode CTE11 and the 1-2nd contact electrode CTE12 are not limited thereto. The positions of the 1-1st contact electrode CTE11 and the 1-2nd contact electrode CTE12 may be freely designed, within a range in which the 1-1st contact electrode CTE11 and the 1-2nd contact electrode CTE12 may face the 2-1st contact electrode and the 2-2nd contact electrode formed on the inner surface of the cover 1000. For example, the 1-1st contact electrode CTE11 and the 1-2nd contact electrode CTE12 may be formed on a side plate SP of the semi-exterior portion 1100a.

The 1-1st contact electrode CTE11 and the 1-2nd contact electrode CTE12 may be formed on a surface of the semi-exterior portion 1100a to be separated from each other. Here, the separation between the 1-1st contact electrode CTE11 and the 1-2nd contact electrode CTE12 may denote a state in which the 1-1st contact electrode CTE11 and the 1-2nd contact electrode CTE12 are not electrically and physically connected to each other.

Referring to FIGS. 4A and 4B, the top plate TP of the semi-exterior portion 1100a may include a 1-1st magnetic substance MG11 and a 1-2nd magnetic substance MG12. For example, the 1-1st contact electrode CTE11 and the 1-2nd contact electrode CTE12 may be formed on an upper surface TP_S1 of the top plate TP of the semi-exterior portion 1100a, and the 1-1st magnetic substance MG11 corresponding to the 1-1st contact electrode CTE11 and the 1-2nd magnetic substance MG12 corresponding to the 1-2nd contact electrode CTE12 may be arranged on a lower surface TP_S2 of the top plate TP of the semi-exterior portion 1100a. According to an embodiment, a first electrically conductive wire W11 connected to the 1-1st contact electrode CTE11 and a second electrically conductive wire W12 connected to the 1-2nd contact electrode CTE12 may be arranged on the lower surface TP_S2 of the top plate TP. Here, the top plate TP may include a first contact hole CH1 (of FIG. 6) and a second contact hole CH2 (of FIG. 6) penetrating the upper surface TP_S1 and the lower surface TP_S2. The 1-1st contact electrode CTE11 and the first electrically conductive wire W11 may be connected to each other through the first contact hole CH1 (of FIG. 6), and the 1-2nd contact electrode CTE12 and the second electrically conductive wire W12 may be connected to each other through the second contact hole CH2 (of FIG. 6). Referring to FIG. 3 again, the semi-exterior portion 1100a may include the button 1200 on the side plate SP. When a user input is applied to the button 1200, a fastening or a separating operation between the semi-exterior portion 1100a and the cartridge 2000 may be performed.

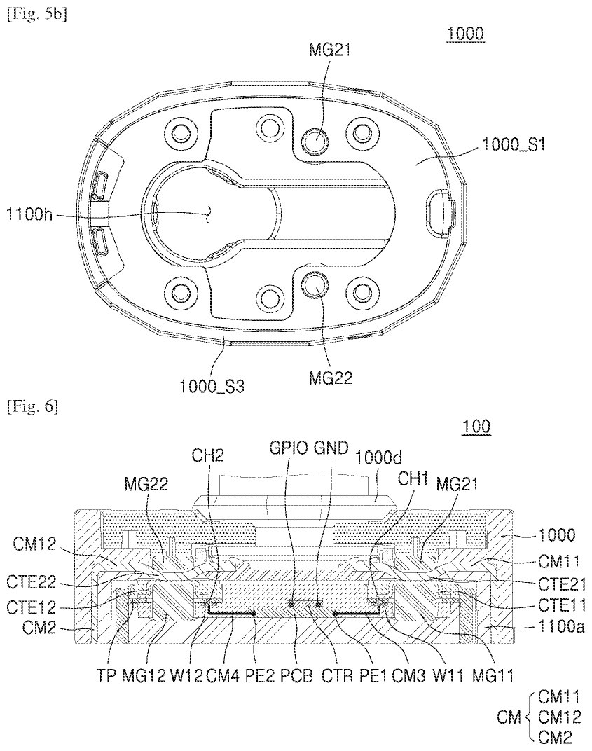

FIG. 5A is a bottom view of a cover, and FIG. 5B is a plan view of the cover from which a top plate is removed.

Referring to FIGS. 4A and 5A, the cover 1000 may include a 2-1st contact electrode CTE21 and a 2-2nd contact electrode CTE22. For example, the 2-1st contact electrode CTE21 and the 2-2nd contact electrode CTE22 may be arranged on a lower surface 1000_S2 of the cover 1000, and the 2-1 st contact electrode CTE21 and the 2-2nd contact electrode CTE12 may be respectively formed to face the 1-1st contact electrode CTE11 and the 1-2nd contact electrode CTE12 formed on the upper surface TP_S1 of the semi-exterior portion 1100a.

The 2-1st contact electrode CTE21 and the 2-2nd contact electrode CTE22 may be electrically connected to each other by a connection portion CM. The connection portion CM may include a 1-1st connection portion CM11, a 1-2nd connection portion CM12, and a second connection portion CM2. The 1-1st connection portion CM11, the 1-2nd connection portion CM12, and the second connection portion CM2 may include conductive materials. The conductive materials may include metal materials having conductive properties. For example, the conductive materials may include one or more of Cu, Ni, Ti, Al, Ag, Au, and Cr.

The second connection portion CM2 may be formed throughout an inner surface of a side surface 1000_S3 of the cover 1000. The 1-1st connection portion CM11 and the 1-2nd connection portion CM12 may be formed on the lower surface 1000_S2, the 1-1st connection portion CM11 may connect the 2-1st contact electrode CTE21 with the second connection portion CM2, and the 1-2nd connection portion CM12 may connect the 2-2nd contact electrode CTE22 with the second connection portion CM2.

FIG. 5A illustrates that the 2-1st contact electrode CTE21, the 2-2nd contact electrode CTE22, the 1-1st connection portion CM11, the 1-2nd connection portion CM12, and the second connection portion CM2 are separate components, for convenience of explanation. However, the 2-1st contact electrode CTE21, the 2-2nd contact electrode CTE22, the 1-1st connection portion CM11, the 1-2nd connection portion CM12, and the second connection portion CM2 may be integrally formed in a manufacturing process.

Referring to FIGS. 5A and 5B, the cover 1000 may include a 2-1st magnetic substance MG21 and a 2-2nd magnetic substance MG22. For example, the 2-1st contact electrode CTE21 and the 2-2nd contact electrode CTE22 may be arranged on the lower surface 1000_S2 of the cover 1000, and the 2-1st magnetic substance MG21 corresponding to the 2-1st contact electrode CTE21 and the 2-2nd magnetic substance MG22 corresponding to the 2-2nd contact electrode CTE22 may be arranged on an upper surface 1000_S1 of the cover 1000, from which the top plate 1000t (of FIG. 1) of the cover 1000 is removed. It may be expected that as a tensile force is applied between the 1-1st magnetic substance MG11 and the 2-1st magnetic substance MG21, accurate connection between the 1-1 st contact electrode CTE11 and the 2-1st contact electrode CTE21 may become possible, and likewise, as a tensile force is applied between the 1-2nd magnetic substance MG12 and the 2-2nd magnetic substance MG22, accurate connection between the 1-2nd contact electrode CTE12 and the 2-2nd contact electrode CTE22 may become possible.

FIG. 6 is a cross-sectional view of an aerosol generating device according to an embodiment for describing a coupling state between contact electrodes when a cover is coupled to a main body. Hereinafter, descriptions that are the same as the descriptions about the components with reference to FIGS. 1 to 5 are not repeated, and a method of determining whether or not the cover 1000 and the main body 1100 are detached from each other is mainly described in detail.

Referring to FIGS. 1 and 6, the semi-exterior portion 1100a may include a printed circuit board PCB on which a controller CTR is arranged or mounted.

The controller CTR may include at least one processor. A processor may be implemented as an array of a plurality of logic gates or may be implemented as a combination of a general-purpose microprocessor and a memory in which a program executable in the microprocessor is stored. Also, it will be understood by one of ordinary skill in the art that the processor may be implemented in other forms of hardware, such as a micro-controller unit.

FIG. 6 illustrates that the printed circuit board PCB is arranged above the semi-exterior portion 1100a, for convenience of explanation. However, the printed circuit board PCB is not limited thereto. In consideration of a connection relationship with other components, the printed circuit board PCB may be arranged below the semi-exterior portion 1100a, on the lower case 1100b, or the like.

The controller CTR may include a ground terminal GND connected to reference power (for example, 0 [V]) and a general-purpose input and output terminal GPIO used for controlling an input and output operation of a signal. The ground terminal GND may be electrically connected to a first pad electrode PE1 of the printed circuit board PCB, and the general-purpose input and output terminal GPIO may be electrically connected to a second pad electrode PE2 of the printed circuit board PCB. According to an embodiment, the 1-1st contact electrode CTE11 may be connected to the first pad electrode PE1 through a third connection portion CM3, and the 1-2nd contact electrode CTE12 may be connected to the second pad electrode PE2 through a fourth connection portion CM4. In other words, the 1-1st contact electrode CTE11 may be connected to the ground terminal GND, and the 1-2nd contact electrode CTE12 may be connected to the general-purpose input and output terminal GPIO.

Here, the third connection portion CM3 and the fourth connection portion CM4 may include conductive clips or C-clips, but are not limited thereto. For example, the third connection portion CM3 and the fourth connection portion CM4 may include wires, flexible printed circuit boards (FPCBs), or cables.

The controller CTR may generally control operations of the aerosol generating device 100. The controller CTR according to an embodiment may determine, based on a change of an input signal received through the general-purpose input and output terminal GPIO, whether or not the cover 1000 and the main body 1100 are detached from each other.

The controller CTR according to an embodiment may transmit an output signal of a high level (for example, 1.8 [V]) through the general-purpose input and output terminal GPIO.

When the cover 1000 is mounted on the main body 1100 (or the semi-exterior portion 1100a), the 2-1st contact electrode CTE21 of the cover 1000 may be electrically and physically connected to the 1-1st contact electrode CTE11 of the semi-exterior portion 1100a, and the 2-2nd contact electrode CTE22 of the cover 1000 may be electrically and physically connected to the 1-2nd contact electrode CTE12 of the semi-exterior portion 1100a.

When the cover 1000 is mounted on the main body 1100, the 1-1st contact electrode CTE11 and the 1-2nd contact electrode CTE12 may be electrically connected to each other through the connection portion CM, and thus, the 1-2nd contact electrode CTE12 may be short-circuited with the 1-1st contact electrode CTE11. That is, the 1-2nd contact electrode CTE12 may be connected to the reference power (for example, 0 [V]), and thus, a signal of the general-purpose input and output terminal GPIO may be changed from a high level to a low level. Here, the signal of the low level may have substantially the same voltage value as the reference power (for example, 0 [V]).

In contrast, when the cover 1000 is separated from the main body 1100, the 1-1st contact electrode CTE11 and the 1-2nd contact electrode CTE12 are not short-circuited with each other, and thus, a signal of the general-purpose input and output terminal GPIO may maintain a high level.

When the signal of the general-purpose input and output terminal GPIO has a high level (for example, 1.8 [V]), the controller CTR may determine that the cover 1000 is separated from the main body 1100. However, when the signal of the general-purpose input and output terminal GPIO is changed from a high level to a low level (for example, 0 [V]), the controller CTR may determine that the cover 1000 is mounted on the main body 1100.

As described above, when whether or not the cover 1000 and the main body 1100 are detached from each other is determined based on a voltage change due to physical coupling of electrodes arranged in the cover 1000 and the main body 1100, errors due to an occurrence of heating noise may be reduced, compared to a case in which whether or not the cover 1000 and the main body 1100 are detached from each other is determined based on a mutual inductance change.

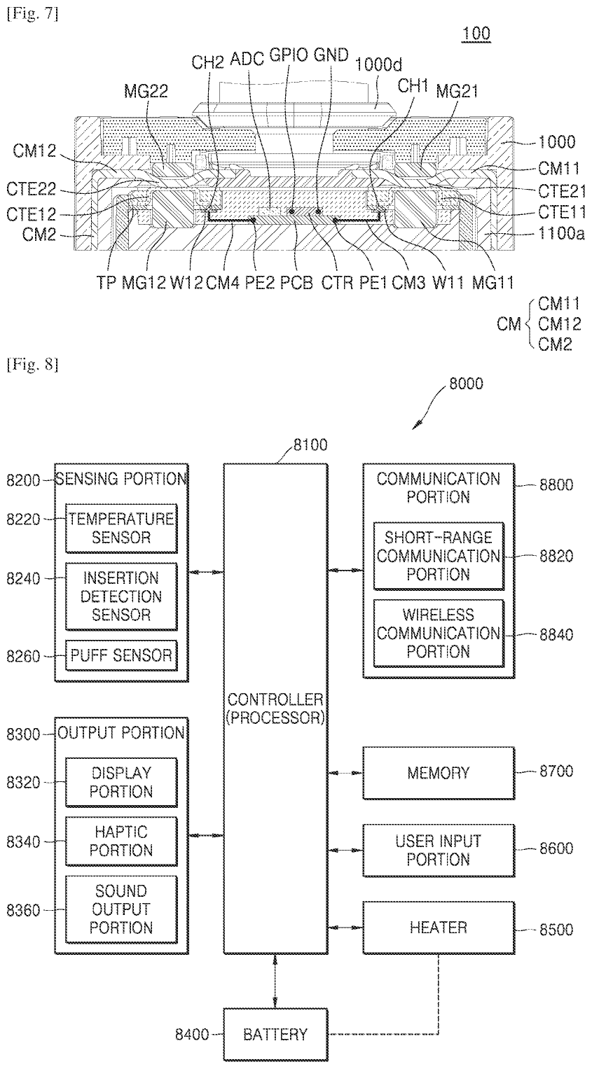

FIG. 7 is a cross-sectional view of an aerosol generating device according to another embodiment for describing a coupling state between contact electrodes when a cover is coupled to a main body.

Referring to FIGS. 6 and 7, the embodiment illustrated in FIG. 7 is substantially the same as the embodiment illustrated in FIG. 6, except that an analog-to-digital converter ADC on the printed circuit board PCB is further included in the embodiment illustrated in FIG. 7. Hereinafter, the same descriptions are not repeated, and a method of determining, by using the analog-to-digital converter ADC, whether or not the cover 1000 and the main body 1100 are detached from each other, is mainly described.

The printed circuit board PCB (or the aerosol generating device 100) may further include the analog-to-digital converter ADC configured to convert an analog input signal to a digital input signal, between the second pad electrode PE2 (or the 1-2nd contact electrode CTE12) and the general-purpose input and output terminal GPIO. The analog-to-digital converter ADC may convert an analog signal value in a predetermined range (for example, 0 [V] to 1.8 [V]) to a digital signal value.

The controller CTR may transmit an output signal of a high level (for example, 1.8 [V]) through the general-purpose input and output terminal GPIO.

When the cover 1000 is mounted on the main body 1100 (or the semi-exterior portion 1100a), the 2-1 st contact electrode CTE21 of the cover 1000 may be electrically and physically connected to the 1-1st contact electrode CTE11 of the semi-exterior portion 1100a, and the 2-2nd contact electrode CTE22 of the cover 1000 may be electrically and physically connected to the 1-2nd contact electrode CTE12 of the semi-exterior portion 1100a.

When the cover 1000 is mounted on the main body 1100, the 1-1st contact electrode CTE11 and the 1-2nd contact electrode CTE12 may be electrically connected to each other through the connection portion CM, and thus, the 1-2nd contact electrode CTE12 may be short-circuited with the 1-1 st contact electrode CTE11. That is, the 1-2nd contact electrode CTE12 may be connected to reference power (for example, 0 [V]), and thus, a signal of the general-purpose input and output terminal GPIO may be changed from a high level to a low level. Here, when the coupling between the electrodes is incomplete even though the cover 1000 is substantially mounted on the main body 1100, the signal of the low level may have a voltage value that is higher than a voltage value of the reference power (for example, 0 [V]).

When the general-purpose input and output terminal GPIO receives a digital input signal that is equal to or less than a predetermined threshold value (for example, a digital signal value corresponding to 0.7 [V]), the controller CTR may determine that the cover 1000 is mounted on the main body 1100. The predetermined threshold value may be experimentally/statistically optimized.

In contrast, when the cover 1000 is separated from the main body 1100, the 1-1st contact electrode CTE11 and the 1-2nd contact electrode CTE12 are not short-circuited with each other, and thus, a signal of the general-purpose input and output terminal GPIO may maintain a high level.

When the signal of the general-purpose input and output terminal GPIO has a high level (for example, a digital signal value corresponding to 1.8 [V]), the controller CTR may determine that the cover 1000 is separated from the main body 1100.

As described above, when a margin of the low level signal is permitted by using the analog-to-digital converter ADC, the operation of the aerosol generating device 100 may be guaranteed when the cover 1000 and the main body 1100 are substantially coupled to each other even though the coupling is complete.

FIG. 8 is a block diagram of an aerosol generating device 8000 according to another embodiment.

The aerosol generating device 8000 may include a controller 8100, a sensing unit 8200, an output unit 8300, a battery 8400, a heater 8500, a user input unit 8600, a memory 8700, and a communication unit 8800. However, the internal structure of the aerosol generating device 8000 is not limited to those illustrated in FIG. 8. That is, according to the design of the aerosol generating device 8000, it will be understood by one of ordinary skill in the art that some of the components shown in FIG. 8 may be omitted or new components may be added.

The sensing unit 8200 may sense a state of the aerosol generating device 8000 and a state around the aerosol generating device 8000, and transmit sensed information to the controller 8100. Based on the sensed information, the controller 8100 may control the aerosol generating device 8000 to perform various functions, such as controlling an operation of the heater 8500, limiting smoking, determining whether an aerosol generating article (e.g., a cigarette, a cartridge, or the like) is inserted, displaying a notification, or the like.

The sensing unit 8200 may include at least one of a temperature sensor 8220, an insertion detection sensor 8240, and a puff sensor 8260, but is not limited thereto.

The temperature sensor 8220 may sense a temperature at which the heater 8500 (or an aerosol generating material) is heated. The aerosol generating device 8000 may include a separate temperature sensor for sensing the temperature of the heater 8500, or the heater 8500 may serve as a temperature sensor. Alternatively, the temperature sensor 8220 may also be arranged around the battery 8400 to monitor the temperature of the battery 8400.

The insertion detection sensor 8240 may sense insertion and/or removal of an aerosol generating article. For example, the insertion detection sensor 8240 may include at least one of a film sensor, a pressure sensor, an optical sensor, a resistive sensor, a capacitive sensor, an inductive sensor, and an infrared sensor, and may sense a signal change according to the insertion and/or removal of an aerosol generating article.

The puff sensor 8260 may sense a user's puff on the basis of various physical changes in an airflow passage or an airflow channel. For example, the puff sensor 8260 may sense a user's puff on the basis of any one of a temperature change, a flow change, a voltage change, and a pressure change.

The sensing unit 8200 may include, in addition to the temperature sensor 8220, the insertion detection sensor 8240, and the puff sensor 8260 described above, at least one of a temperature/humidity sensor, a barometric pressure sensor, a magnetic sensor, an acceleration sensor, a gyroscope sensor, a location sensor (e.g., a global positioning system (GPS)), a proximity sensor, and a red-green-blue (RGB) sensor (illuminance sensor). Because a function of each of sensors may be intuitively inferred by one of ordinary skill in the art from the name of the sensor, a detailed description thereof may be omitted.

The output unit 8300 may output information on a state of the aerosol generating device 8000 and provide the information to a user. The output unit 8300 may include at least one of a display unit 8320, a haptic unit 8340, and a sound output unit 8360, but is not limited thereto. When the display unit 8320 and a touch pad form a layered structure to form a touch screen, the display unit 8320 may also be used as an input device in addition to an output device.

The display unit 8320 may visually provide information about the aerosol generating device 8000 to the user. For example, information about the aerosol generating device 8000 may mean various pieces of information, such as a charging/discharging state of the battery 8400 of the aerosol generating device 8000, a preheating state of the heater 8500, an insertion/removal state of an aerosol generating article, or a state in which the use of the aerosol generating device 8000 is restricted (e.g., sensing of an abnormal object), or the like, and the display unit 8320 may output the information to the outside. The display unit 8320 may be, for example, a liquid crystal display panel (LCD), an organic light-emitting diode (OLED) display panel, or the like. In addition, the display unit 8320 may be in the form of a light-emitting diode (LED) light-emitting device.

The haptic unit 8340 may tactilely provide information about the aerosol generating device 8000 to the user by converting an electrical signal into a mechanical stimulus or an electrical stimulus. For example, the haptic unit 8340 may include a motor, a piezoelectric element, or an electrical stimulation device.

The sound output unit 8360 may audibly provide information about the aerosol generating device 8000 to the user. For example, the sound output unit 8360 may convert an electrical signal into a sound signal and output the same to the outside.

The battery 8400 may supply power used to operate the aerosol generating device 8000. The battery 8400 may supply power such that the heater 8500 may be heated. In addition, the battery 8400 may supply power required for operations of other components (e.g., the sensing unit 8200, the output unit 8300, the user input unit 8600, the memory 8700, and the communication unit 8800) in the aerosol generating device 8000. The battery 8400 may be a rechargeable battery or a disposable battery. For example, the battery 8400 may be a lithium polymer (LiPoly) battery, but is not limited thereto.

The heater 8500 may receive power from the battery 8400 to heat an aerosol generating material. Although not illustrated in FIG. 8, the aerosol generating device 8000 may further include a power conversion circuit (e.g., a direct current (DC)/DC converter) that converts power of the battery 8400 and supplies the same to the heater 8500. In addition, when the aerosol generating device 8000 generates aerosols in an induction heating method, the aerosol generating device 8000 may further include a DC/alternating current (AC) that converts DC power of the battery 8400 into AC power.

The controller 8100, the sensing unit 8200, the output unit 8300, the user input unit 8600, the memory 8700, and the communication unit 8800 may each receive power from the battery 8400 to perform a function. Although not illustrated in FIG. 8, the aerosol generating device 8000 may further include a power conversion circuit that converts power of the battery 8400 to supply the power to respective components, for example, a low dropout (LDO) circuit, or a voltage regulator circuit.

In an embodiment, the heater 8500 may be formed of any suitable electrically resistive material. For example, the suitable electrically resistive material may be a metal or a metal alloy including titanium, zirconium, tantalum, platinum, nickel, cobalt, chromium, hafnium, niobium, molybdenum, tungsten, tin, gallium, manganese, iron, copper, stainless steel, nichrome, or the like, but is not limited thereto. In addition, the heater 8500 may be implemented by a metal wire, a metal plate on which an electrically conductive track is arranged, a ceramic heating element, or the like, but is not limited thereto.

In another embodiment, the heater 8500 may be a heater of an induction heating type. For example, the heater 8500 may include a susceptor that heats an aerosol generating material by generating heat through a magnetic field applied by a coil.

The user input unit 8600 may receive information input from the user or may output information to the user. For example, the user input unit 8600 may include a key pad, a dome switch, a touch pad (a contact capacitive method, a pressure resistance film method, an infrared sensing method, a surface ultrasonic conduction method, an integral tension measurement method, a piezo effect method, or the like), a jog wheel, a jog switch, or the like, but is not limited thereto. In addition, although not illustrated in FIG. 8, the aerosol generating device 8000 may further include a connection interface, such as a universal serial bus (USB) interface, and may connect to other external devices through the connection interface, such as the USB interface, to transmit and receive information, or to charge the battery 8400.

The memory 8700 is a hardware component that stores various types of data processed in the aerosol generating device 8000, and may store data processed and data to be processed by the controller 8100. The memory 8700 may include at least one type of storage medium from among a flash memory type, a hard disk type, a multimedia card micro type memory, a card-type memory (for example, secure digital (SD) or extreme digital (XD) memory, etc.), random access memory (RAM), static random access memory (SRAM), read-only memory (ROM), electrically erasable programmable read-only memory (EEPROM), programmable read-only memory (PROM), a magnetic memory, a magnetic disk, and an optical disk. The memory 8700 may store an operation time of the aerosol generating device 8000, the maximum number of puffs, the current number of puffs, at least one temperature profile, data on a user's smoking pattern, etc.

The communication unit 8800 may include at least one component for communication with another electronic device. For example, the communication unit 8800 may include a short-range wireless communication unit 8820 and a wireless communication unit 8840.

The short-range wireless communication unit 8820 may include a Bluetooth communication unit, a Bluetooth Low Energy (BLE) communication unit, a near field communication unit, a wireless LAN (WLAN) (Wi-Fi) communication unit, a Zigbee communication unit, an infrared data association (IrDA) communication unit, a Wi-Fi Direct (WFD) communication unit, an ultra-wideband (UWB) communication unit, an Ant+ communication unit, or the like, but is not limited thereto.

The wireless communication unit 8840 may include a cellular network communication unit, an Internet communication unit, a computer network (e.g., local area network (LAN) or wide area network (WAN)) communication unit, or the like, but is not limited thereto. The wireless communication unit 8840 may also identify and authenticate the aerosol generating device 8000 within a communication network by using subscriber information (e.g., International Mobile Subscriber Identifier (IMSI)).

The controller 8100 may control general operations of the aerosol generating device 8000. In an embodiment, the controller 8100 may include at least one processor. The processor may be implemented as an array of a plurality of logic gates or may be implemented as a combination of a general-purpose microprocessor and a memory in which a program executable by the microprocessor is stored. It will be understood by one of ordinary skill in the art that the processor may be implemented in other forms of hardware.

The controller 8100 may control the temperature of the heater 8500 by controlling supply of power of the battery 8400 to the heater 8500. For example, the controller 8100 may control power supply by controlling switching of a switching element between the battery 8400 and the heater 8500. In another example, a direct heating circuit may also control power supply to the heater 8500 according to a control command of the controller 8100.

The controller 8100 may analyze a result sensed by the sensing unit 8200 and control subsequent processes to be performed. For example, the controller 8100 may control power supplied to the heater 8500 to start or end an operation of the heater 8500 on the basis of a result sensed by the sensing unit 8200. As another example, the controller 8100 may control, based on a result sensed by the sensing unit 8200, an amount of power supplied to the heater 8500 and the time the power is supplied, such that the heater 8500 may be heated to a certain temperature or maintained at an appropriate temperature.

The controller 8100 may control the output unit 8300 on the basis of a result sensed by the sensing unit 8200. For example, when the number of puffs counted through the puff sensor 8260 reaches a preset number, the controller 8100 may notify the user that the aerosol generating device 8000 will soon be terminated through at least one of the display unit 8320, the haptic unit 8340, and the sound output unit 8360.

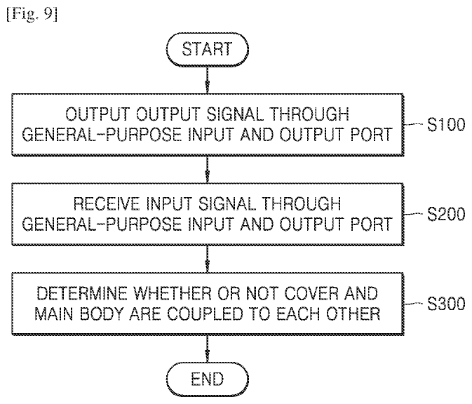

FIG. 9 is a flowchart for describing a method, performed by an aerosol generating device, of determining whether or not a cover and a main body are detached from each other.

Referring to FIGS. 1 to 9, an operation method of the aerosol generating device 100 according to an embodiment may include outputting (S100) an output signal through the general-purpose input and output terminal GPIO, receiving (S200) an input signal through the general-purpose input and output terminal GPIO, and determining (S300) whether or not the cover 1000 and the main body 100 are coupled to each other.

Here, the aerosol generating device 100 may include the main body 1100, the cover 1000, and the controller CTR. The main body 1100 may include the semi-exterior portion 1100a on a surface of which the 1-1st contact electrode CTE11 connected to the ground terminal GND of the controller CTR and the 1-2nd contact electrode CTE12 connected to the general-purpose input and output terminal GPIO of the controller CTR are formed.

The cover 1000 may be detachably coupled to the main body 1100 and may include the 2-1st contact electrode CTE21 corresponding to the 1-1st contact electrode CTE11 and the 2-2nd contact electrode CTE22 corresponding to the 1-2nd contact electrode CTE12. The 2-1st contact electrode CTE21 and the 2-2nd contact electrode CTE22 may be electrically connected to each other by the connection portion CM. The connection portion CM may include the 1-1st connection portion CM11, the 1-2nd connection portion CM12, and the second connection portion CM2. The 1-1 st connection portion CM11, the 1-2nd connection portion CM12, and the second connection portion CM2 may include conductive materials. The conductive materials may include metal materials having conductive properties. For example, the conductive materials may include one or more of Cu, Ni, Ti, Al, Ag, Au, and Cr.

The controller CTR may include the ground terminal GND connected to reference power (for example, 0 [V]) and the general-purpose input and output terminal GPIO used for controlling an input and output operation of a signal.

In detail, in operation S100 of outputting the output signal through the general-purpose input and output terminal GPIO, the controller CTR may transmit an output signal of a high level (for example, 1.8 [V]) through the general-purpose input and output terminal GPIO.

In operation S200 of receiving the input signal through the general-purpose input and output terminal GPIO, when the cover 1000 is mounted on the main body 1100, the 1-1st contact electrode CTE11 and the 1-2nd contact electrode CTE12 may be electrically connected to each other through the connection portion CM, and thus, the 1-2nd contact electrode CTE12 and the 1-1st contact electrode CTE11 may be short-circuited with each other. That is, the 1-2nd contact electrode CTE12 may be connected to the reference power (for example, 0 [V]), and thus, a signal of the general-purpose input and output terminal GPIO may be changed from a high level to a low level. Here, the signal of the low level may have substantially the same voltage value as the reference power (for example, 0 [V]).

In contrast, when the cover 1000 is separated from the main body 1100, the 1-1st contact electrode CTE11 and the 1-2nd contact electrode CTE12 are not short-circuited with each other, and thus, a signal of the general-purpose input and output terminal GPIO may maintain a high level.

In operation S300 of determining whether or not the cover 1000 and the main body 1100 are coupled to each other, the controller CTR may determine that the cover 1000 is separated from the main body 1100 when the signal of the general-purpose input and output terminal GPIO has a high level (for example, 1.8 [V]). In contrast, when the signal of the general-purpose input and output terminal GPIO is changed from a high level to a low level (for example, 0 [V]), the controller CTR may determine that the cover 1000 is mounted on the main body 1100.

Here, when the coupling between the electrodes is incomplete even though the cover 1000 is substantially mounted on the main body 1100, the signal of the low level may have a voltage value that is higher than a voltage value of the reference power (for example, 0 [V]). The aerosol generating device 100 according to an embodiment may further include the analog-to-digital converter ADC for converting an analog input signal to a digital input signal, between the 1-2nd contact electrode CTE12 and the general-purpose input and output terminal GPIO. When the general-purpose input and output terminal GPIO receives a digital input signal that is equal to or less than a predetermined threshold value (for example, a digital signal value corresponding to 0.7 [V]), the controller CTR may determine that the cover 1000 is mounted on the main body 1100. The predetermined threshold value may be experimentally/statistically optimized.

An embodiment may be implemented in the form of a recording medium including a computer-executable instruction, such as a program module executed by a computer. The computer-readable recording medium may be an arbitrary available medium accessible by a computer and includes all of volatile and non-volatile media and detachable and non-detachable media. Also, the computer-readable recording medium may include both of a computer storage medium and a communication medium. The computer storage recording medium includes all of volatile and non-volatile media and detachable and non-detachable media that are realized by an arbitrary method or technique for storing information, such as computer-readable instructions, data structures, program modules, or other data. The communication medium typically includes computer-readable instructions, data structures, program modules, or other data of modulated data signals, or other transmission mechanisms, and includes an arbitrary data transmission mechanism.

The descriptions of the above-described embodiments are merely examples, and it will be understood by one of ordinary skill in the art that various changes and equivalents thereof may be made. Therefore, the scope of the disclosure should be defined by the appended claims, and all differences within the scope equivalent to those described in the claims will be construed as being included in the scope of protection defined by the claims.

1. An aerosol generating device comprising:
a main body including a semi-exterior portion on a surface of which a 1-1st contact electrode and a 1-2nd contact electrode are formed to be apart from each other;
a cover detachably coupled to the main body and including a 2-1st contact electrode corresponding to the 1-1st contact electrode and a 2-2nd contact electrode corresponding to the 1-2nd contact electrode; and
a controller configured to determine that the cover is mounted on the main body when the 1-1st contact electrode and the 1-2nd contact electrode are electrically connected to each other.

2. The aerosol generating device of claim 1, wherein the cover includes an upper surface corresponding to the surface of the semi-exterior portion and a side surface extending in a thickness direction along a circumference of the upper surface, and
the 2-1st contact electrode and the 2-2nd contact electrode are arranged on an inner surface of the upper surface and electrically connected to each other.

3. The aerosol generating device of claim 2, wherein the cover includes a connection portion electrically connecting the 2-1st contact electrode with the 2-2nd contact electrode, wherein the connection portion is formed throughout an inner surface of the side surface.

4. The aerosol generating device of claim 1, wherein the controller includes: a ground terminal connected to the 1-1st contact electrode; and a general-purpose input and output terminal connected to the 1-2nd contact electrode.

5. The aerosol generating device of claim 4, wherein the controller is further configured to transmit an output signal of a high level through the general-purpose input and output terminal.

6. The aerosol generating device of claim 5, wherein the controller is further configured to, when the controller receives an input signal of a low level through the general-purpose input and output terminal, determine that the cover is mounted on the main body.

7. The aerosol generating device of claim 5, further comprising an analog-to-digital converter between the 1-2nd contact electrode and the general-purpose input and output terminal, the analog-to-digital converter being configured to convert an analog input signal to a digital input signal.

8. The aerosol generating device of claim 7, wherein the controller is further configured to, when the general-purpose input and output terminal receives the digital input signal that is less than or equal to a predetermined threshold value, determine that the cover is mounted on the main body.

9. The aerosol generating device of claim 1, wherein the semi-exterior portion includes: a 1-1st magnetic substance arranged at an inner portion of the 1-1st contact electrode; and a 1-2nd magnetic substance arranged at an inner portion of the 1-2nd contact electrode.

10. The aerosol generating device of claim 9, wherein the cover includes: a 2-1st magnetic substance arranged at an inner portion of the 2-1st contact electrode and generating a tensile force with respect to the 1-1st magnetic substance; and a 2-2nd magnetic substance arranged at an inner portion of the 2-2nd contact electrode and generating a tensile force with respect to the 1-2nd magnetic substance.

11. An operating method of an aerosol generating device including a main body that includes a semi-exterior portion on a surface of which a 1-1st contact electrode and a 1-2nd contact electrode are formed to be apart from each other, and a cover detachably coupled to the main body and including a 2-1st contact electrode corresponding to the 1-1st contact electrode and a 2-2nd contact electrode corresponding to the 1-2nd contact electrode, the method comprising:
transmitting an output signal of a high level to a general-purpose input and output terminal;
receiving an input signal through the general-purpose input and output terminal; and
determining, based on a change of the input signal, whether or not the cover and the main body are coupled to each other.

12. The operating method of claim 11, wherein the 2-1st contact electrode and the 2-2nd contact electrode are electrically connected to each other.

13. The operating method of claim 11, wherein the determining of whether or not the cover and the main body are coupled to each other includes determining that the cover is mounted on the main body, when the input signal has a low level.

14. The operating method of claim 11, wherein the aerosol generating device further includes an analog-to-digital converter between the 1-2nd contact electrode and the general-purpose input and output terminal, the analog-to-digital converter being configured to convert an analog input signal to a digital input signal.

15. The operating method of claim 14, wherein the determining of whether or not the cover and the main body are coupled to each other includes determining that the cover is mounted on the main body, when the digital input signal is less than or equal to a predetermined threshold value.
